(19) United States
(12) Patent Application Publication
(10) Pub. No.: US 2007/0034957 A1
(43) Pub. Date: Feb. 15, 2007

(54) Electrostatic foot for non-permanent attachment

(76) Inventors: Richard Jeffery Wagner, Torrance, CA (US); D. Hobson Lane, Hermosa Beach, CA (US)

Correspondence Address: CARMEN B. PATTI & ASSOCIATES, LLC, ONE NORTH LASALLE STREET, 44TH FLOOR, CHICAGO, IL, 60602, US

(21) Appl. No.: 11/202,662

(22) Filed: Aug. 12, 2005

(51) Int. Cl. H01L 23/62

(52) U.S. Cl. 257/355

(57) ABSTRACT

An apparatus in one example has: an electrostatic device having an engagement portion; and an attractive electrostatic force selectively applicable by the electrostatic device to the engagement portion for at least one of holding the electrostatic device or providing locomotion to the electrostatic device.

### TECHNICAL FIELD

The invention relates generally to electrostatic holding apparatus, and more particularly to an electrostatic holding apparatus useful for non-permanent attachment.

### BACKGROUND

Space robot locomotion involves a number of tough problems for walking robots that must traverse exteriors of space vehicles. In zero gravity, a robot must maintain a positive grip on the space vehicle at all times or else it will simply drift away from the vehicle. Additionally, significant positive grip force must be maintained to resist small disturbances from space vehicle thrusting and control moments.

Several problems that arise due to space robot locomotion are as follows. One problem is “what can the robot hang onto?” Another problem is “how to avoid damaging delicate surfaces?” A further problem is “how can it be assured that low forces and moments are induced into delicate space structures?”

A conventional approach to robot locomotion in zero gravity is to use a mechanical gripper (manipulator) to physically hang on to a space vehicle structure, such as astronaut EVA (Extra-Vehicular Activity) handrails. However, the handrails are typically not available at all locations that a space robot, for example, might need to go. Another approach is to use dry adhesive “gecko feet,” but these require a pull-off force that might damage delicate surfaces such as multi-layer insulation, mirrors, and solar cells. They can also induce undesired loads into gossamer-like structures.

### SUMMARY

One implementation encompasses an apparatus. The apparatus may comprise: an electrostatic device having an engagement portion; and an attractive electrostatic force selectively applicable by the electrostatic device to the engagement portion for at least one of holding the electrostatic device or providing locomotion to the electrostatic device.

Another implementation encompasses an apparatus. The apparatus may comprise: a device having a high voltage source, the high voltage source capable of generating a static voltage; the device having a plurality of feet, each of the plurality of feet having; a pad capable of maintaining a static voltage; an insulation layer disposed on a bottom surface of the pad, the insulation layer preventing the pad from dissipating the static voltage; a ground element electrically connecting the pad to a high voltage source; and a dielectric layer disposed on a bottom surface of the insulation layer, the dielectric layer accumulating an electrostatic charge upon application of the static voltage thereto, and electrical control circuitry, the electrical control circuitry structured to selectively deliver the static voltage to each of the plurality of legs.

Another implementation encompasses a method. This embodiment of the method may comprise: non-permanently securing a device to a surface of an object through application of a static voltage to a portion of the device to establish an attractive electrostatic force between the device and the surface of the object.

### DESCRIPTION OF THE DRAWINGS

Features of exemplary implementations of the invention will become apparent from the description, the claims, and the accompanying drawings in which:

FIG. 1 shows a top perspective view of one embodiment of a robot having an electrostatic holding apparatus according to the present method and apparatus.

FIG. 2 shows an exploded top perspective view of one embodiment of a foot of the device shown in FIG. 1.

FIGS. 3 and 4 show a top perspective view and a bottom perspective view of the embodiment of the foot shown in FIG. 2.

FIG. 5 shows one embodiment of a schematic representing electrical control circuitry for use with the FIG. 1 device.

### DETAILED DESCRIPTION

A device, according to the present method and apparatus, is capable of being non-permanently secured to the surface of another object through application of a static voltage to a portion of the device to establish an attractive electrostatic force between the device and the object. Through creating an electrostatic force between the device and the object, the device may be non-permanently secured to the object though non-mechanical and non-magnetic means, making the device particularly useful in zero-gravity environments.

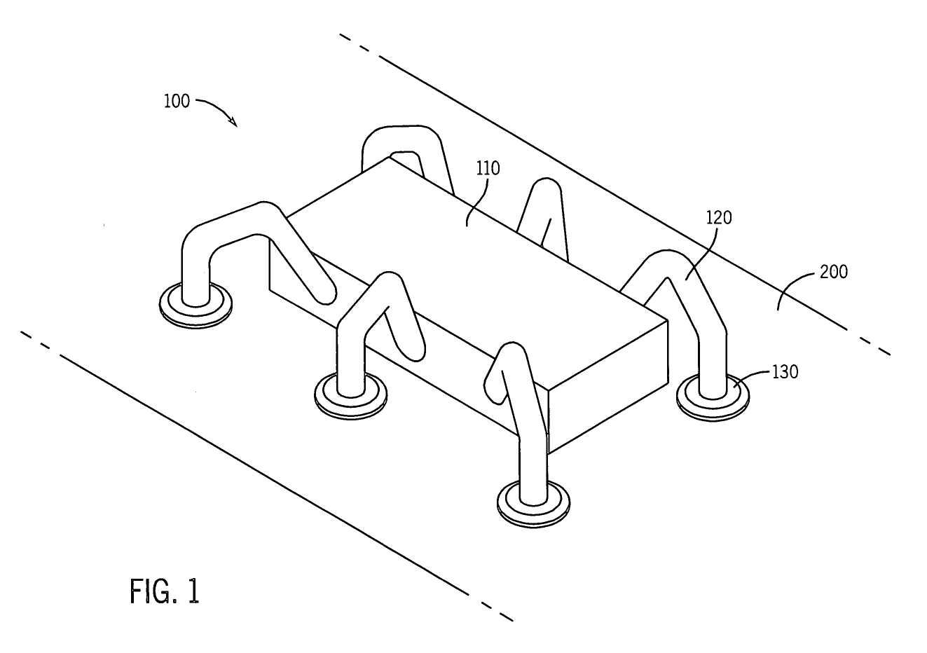

FIG. 1 shows a top view perspective view of one embodiment of the invention, In one embodiment, device 100, which is to be non-permanently secured to the surface of another object 200, may be a robot capable of locomotion. As depicted the robot may have six legs 120, each leg 120 mechanically and electrically connected to chassis 110 and having a foot 130. Each foot 130 of this embodiment of device 100 may have a pad 131, ground 132, insulation layer 133, and dielectric layer 134. Within chassis 110 is a high voltage source (not shown) and electrical control circuitry, each of which will be described in greater detail below.

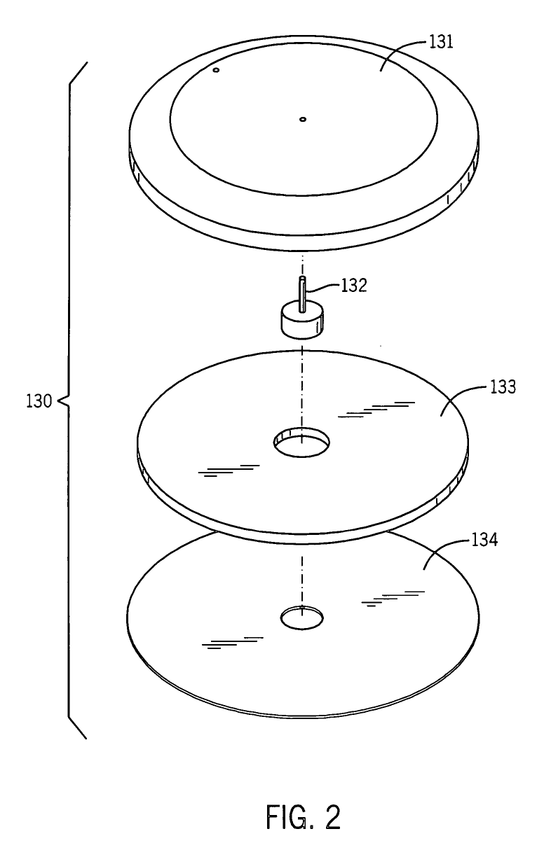

FIG. 2 shows an exploded top perspective view of one embodiment of foot 130 as shown in FIG. 1. The high voltage source (not shown) provides a static voltage to each pad 131 of foot 130, each pad 131 being capable of maintaining a static voltage. Pad 131 maybe made of any conductive or semi-conductive material capable of maintaining a static charge. In the embodiment shown, the pad 131 may be made of materials, such as Pb, Sn, Al., Mylar, combinations thereof, and any other conductive or semi-conductive material such as carbon-impregnated plastic or other materials known in the art.

Positioned below each pad 131 is insulation layer 133. Insulation layer 133 prevents pad 131 from dissipating the static voltage, allowing the charge to build up and creating an electrostatic charge on foot 130. Positioned below each insulation layer 133 is a respective dielectric layer 134, which comes in physical contact with object 200, to which device 100 is non-permanently secured. Because pad 131 maintains a static voltage, an attractive electrostatic force is created between each foot 130 of each leg 120 and object 120. In embodiments of the present method and apparatus, Aluminum or Copper may be used for the pad 131, Mylar or Kaplan for the insulation layer 133, and Teflon or polypropylene for any other incidental insulators. The dielectric layer may be made of a conductive or semi-conductive material selected from a group comprised of, for example, Mylar (polyester), Kapton (polyimide), polyethylene, etc. In general these elements form an engagement portion.

In general voltage is applied to a disc which is a metallic surface (conductive surface) that is insulated from the space craft so the charge will not bleed off quickly. This voltage must be applied relative to a voltage of the space craft so there needs to be a connection to the surface of the space craft. This touching of the space craft may be accomplished via a button in the middle of the foot, a plurality of buttons, a ring, or by dragging a tail, etc. The space craft may, for example, be at a 1000 volt level. The disc must then have a voltage relative to the 1000 volts, in other words the 1000 volts would be the “ground”. The voltage that is applied to the disc may be such as to provide 10,000 volts measured from disc to space craft. DC or AC voltage may be used.

In the robot device of FIG. 1, electrical control circuitry is capable of turning on and off the application of voltage to each leg 120. When the voltage is applied to one leg 120, an electrostatic charge is built up on leg 120, creating an attractive electrostatic force between leg 120 (and consequently device 100) with object 200, i.e., to maintain a positive grip by device 100 (e.g., a rover or walker) on object 200 (e.g., a spacecraft). The electrical control circuitry may selectively apply a voltage to fewer than all of legs 130 such that only some legs 130 have an electrostatic force between it and object 200 at any given time, permitting the remaining legs 130 to move or be repositioned relative to object 200.

In some applications an advantage may be obtained by utilizing bipolar voltage. That is, for each device, two foot pads are used with opposite voltage (positive and negative) applied. Under some operating conditions, this type of bipolar device can have superior adhesive qualities, particularly when used with insulating space structure surfaces.

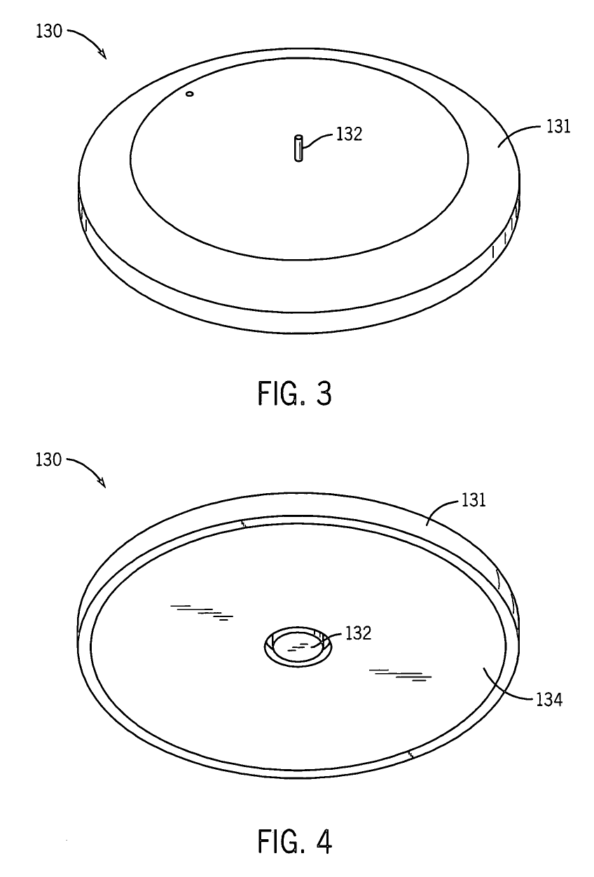

FIGS. 3 and 4 show a top perspective view and a bottom perspective view, respectively, of the embodiment of foot 130 shown in FIG. 2 once assembled. Foot 130, and consequently pad 131, insulation layer (not visible once assembled), and dielectric layer 134, may be of any shape. FIG. 2 shows the components of foot 130 as being circular and flat for convenience, but any shape may be employed. Certain shapes may be better for use with a particular configuration of an object to which foot 130 is electrostatically attracted. For instance, if object 200 is a spacecraft, the particular shape of the spacecraft may affect the shape of foot 130 in that foot 130 may need to fit between other components of the spacecraft. In addition, foot 130 need not be perfectly flat. For instance, if foot 130 is tubular or spherical, it would have a rounded shape that compliments the shape of object 200 to ensure that entire dielectric layer 134, or at least a significant portion of dielectric layer 134 are in contact with the spacecraft. The degree of electrostatic attraction will depend in part, on the surface area of dielectric layer 134 in contact with object 200, so the more surface area in contact, the greater the attractive force there between.

According to the following formula:
F=(ε₀−A−V₂)/2d²

in which F is the attractive force in Newtons, ε₀ is the constant of permittivity (8.85×1012 Newton-meters squared per Coulomb squared), A is the area of the foot in m², V is the voltage, and d is the thickness of the dielectric layer in meters the degree to which foot 130 is electrostaticly attracted to another object can be calculated. As an example, N the dielectric layer has a thickness of 0.1 mm, has a surface area of 1 cm², and about 4,000 volts are applied, the attractive force will be about 0.7 Newtons. In still another example, the foot has a two inch (2″) diameter, the dielectric layer is one (1) milli-inch thick, and 1,000 volts are applied, the holding force will be approximately three (3) pounds.

Referring again to the embodiment of device 100 shown in FIG. 1, the device has six moveable legs 120 operatively secured to chassis 110. The electrical control circuitry (not visible) is structured such that voltage is applied to three of the legs 120 and turned off to the remaining three legs 120. Legs 120 that do not have voltage applied thereto will not be electrostaticly attracted to object 200 and can move forward. Then, the three legs 120 that without a voltage applied thereto will have a voltage applied thereto and the three legs 120 that previously had a voltage applied thereto will have the voltage removed such that the first three legs 120 are then electrostaticly attracted to object 200 and the other three legs 120 can move forward, allowing device 100 to move along object, i.e., in a “spider like” fashion.

By creating the electrostatic attractive force, there is no need to force separation as is required by the use of “gecko feet” or a magnetic attractive force. Delicate surfaces, such as mirrors, layered insulation surfaces, and solar cells, can be damaged when trying to remove the feet 130 from the object 200. By creating an electrostatic attractive force, once the voltage is removed and the attractive force is ended, foot 130 can be removed or otherwise separated from object 200 without damaging object.

However, with some dielectric film materials surface charge buildup can cause continued adhesion after voltage is removed. For this case, a reversed polarity voltage pulse may be used to unstick the device.

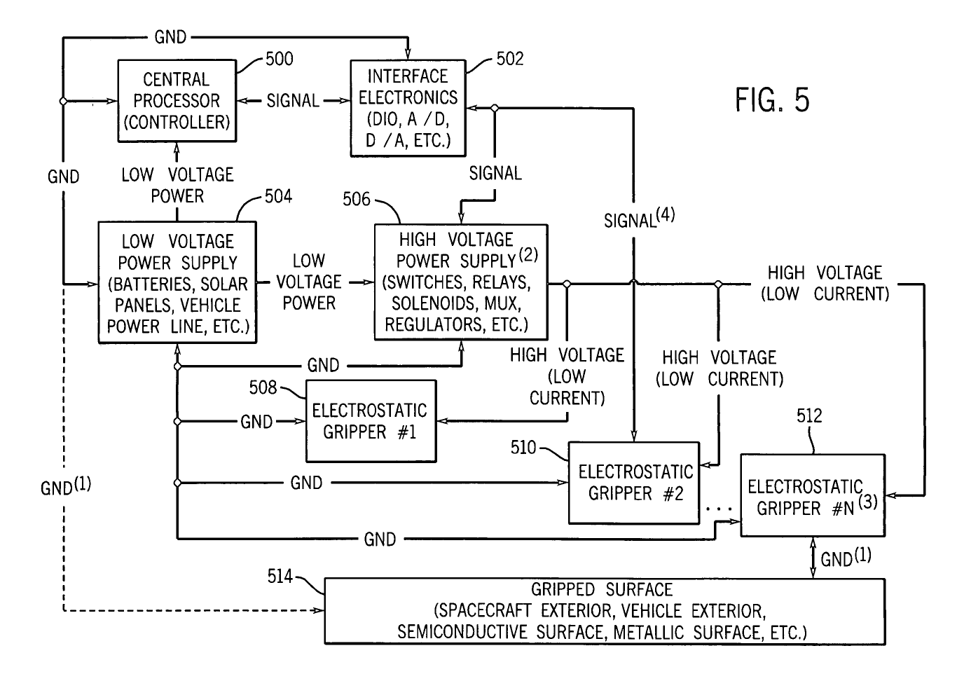

FIG. 5 shows one embodiment of a schematic representing the electrical control circuitry. In this embodiment a central processor 500 may be operatively coupled to interface electronics 502. The central processor 500 may be powered by a low voltage power supply 504. A high voltage power supply 506 may be operatively coupled to the interface electronics 502, and to electrostatic grippers 508, 510, and 512. In the FIG. 5 depiction the interface electronics 502 is currently not applying static voltage to grippers 508 and 510, but is applying static voltage to gripper 512. Thus only gripper 512 is currently adhered to gripped surface 514 by a generated attractive electrostatic force.

One of ordinary skill in the art will recognize after reading the above description that device 100 is only exemplary. Device 100 could alternately be constructed of alternate numbers of legs 130 and the movement of legs 130 could be different. For example, legs 130 could move in series, in a caterpillar-like manner.

Furthermore, the electrical control described above is located within chassis 110 of device 100. Electrical control circuitry could alternately be located in legs 120 or within object 200. Legs 120 would then move between fixed spaces on object 200 and each fixed space would then have voltage applied thereto from object 200. Moreover, though described above with respect to a movable object being electrostaticly attracted to another object, the electrostatic attractive force could also be applied between two relatively stationary objects. For example, in a zero-gravity environment, a tool could be secured to the spacecraft to prevent it from being lost.

The present apparatus in one example may comprise a plurality of components such as one or more of electronic components, hardware components, and computer software components. A number of such components may be combined or divided in the apparatus.

The steps or operations described herein are just exemplary. There may be many variations to these steps or operations without departing from the spirit of the invention. For instance, the steps may be performed in a differing order, or steps may be added, deleted, or modified.

Although exemplary implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

We claim:

1. An apparatus, comprising:
an electrostatic device having an engagement portion; and
an attractive electrostatic force selectively applicable by the electrostatic device to the engagement portion.

2. The apparatus according to claim 1, wherein the engagement portion is in contact with an object, and wherein the engagement portion adheres the electrostatic device to the object when the attractive electrostatic force is applied by the electrostatic device to the engagement portion.

3. The apparatus according to claim 1, wherein the device has a plurality of feet, each of the plurality of feet having:
a pad capable of maintaining a static voltage;
an insulation layer disposed on a bottom surface of the pad, the
insulation layer preventing the pad from dissipating the static voltage;
a ground element electrically connecting the pad to a high voltage source; and
a dielectric layer disposed on a bottom surface of the insulation layer, the dielectric layer accumulating an electrostatic charge upon application of the static voltage thereto.

4. The apparatus according to claim 1, wherein the ground element is a button-type structure that is substantially centrally located in the foot.

5. The apparatus according to claim 1, wherein the ground element extends through apertures in the insulation layer and the dielectric layer.

6. The apparatus according to claim 1, wherein the plurality of feet are moveable, and wherein the device is structured to selectively apply attractive electrostatic forces to respective feet in the plurality of feet such that the feet are moved in a predetermined pattern to provide movement to the device.

7. A method, comprising:
non-permanently securing a device to a surface of an object through application of a static voltage to a portion of the device to establish an attractive electrostatic force between the device and the surface of the object.

8. The method according to claim 7, wherein the device has a plurality of feet, each of the plurality of feet having:
a pad capable of maintaining a static voltage;
an insulation layer disposed on a bottom surface of the pad, the
insulation layer preventing the pad from dissipating the static voltage;
a ground element electrically connecting the pad to a high voltage source; and
a dielectric layer disposed on a bottom surface of the insulation layer,
the dielectric layer accumulating an electrostatic charge upon application of the static voltage thereto, and
wherein the method further comprises applying attractive electrostatic forces to respective feet in the plurality of feet such that the feet are moved in a predetermined pattern to provide movement to the device.

9. The method according to claim 8, wherein the pad is made of a material selected from a group comprised of Aluminum and Copper, wherein the insulation layer is made of a material selected from a group comprised of Mylar (polyester) and Kapton (polyimide), and wherein the dielectric layer is made of a conductive or semi-conductive material selected from a group comprised of Mylar (polyester), Kapton (polyimide), and polyethylene.

10. The method according to claim 7, wherein device further has a chassis and wherein each of the plurality of feet is movably connected to the chassis for locomotion of the device relative to the object.

11. An apparatus comprising:
a device having a high voltage source, the high voltage source capable of generating a static voltage;
the device having a plurality of feet, each of the plurality of feet having:
a pad capable of maintaining a static voltage;
an insulation layer disposed on a bottom surface of the pad, the
insulation layer preventing the pad from dissipating the static voltage;
a ground element electrically connecting the pad to a high voltage source; and
a dielectric layer disposed on a bottom surface of the insulation layer,
the dielectric layer accumulating an electrostatic charge upon application of the static voltage thereto, and electrical control circuitry, the electrical control circuitry structured to selectively deliver the static voltage to each of the plurality of legs.

12. The apparatus according to claim 11, wherein at least some of the feet are in contact with an object, and wherein the feet adhere by the static device to the object when the static voltage is applied by electrical control circuitry to the feet.

13. The apparatus according to claim 12, wherein the plurality of feet are moveable, and wherein the electrical control circuitry is structured to selectively apply attractive electrostatic force created by the static voltages to respective feet of the plurality of feet such that the feet are moved in a predetermined pattern to provide movement to the device.

14. The apparatus according to claim 11, wherein the ground element is a button-type structure that is substantially centrally located in the foot, and wherein the ground element extends through apertures in the insulation layer and the dielectric layer.

15. An apparatus, comprising:
a robotic electrostatic device having a plurality of feet;
each foot of the plurality of feet having at least one engagement portion;
an attractive electrostatic force generated by the robotic electrostatic device, the attractive electrostatic force being selectively applicable by the electrostatic device to respective engagement portions of the plurality of feet; and
wherein the plurality of feet are moveable, and wherein the robotic electrostatic device is structured to selectively apply attractive electrostatic forces to respective feet in the plurality of feet such that the feet are moved in a predetermined pattern to provide movement to the robotic electrostatic device.

16. The apparatus according to claim 15, wherein the engagement portions are in intermittent contact with an object, and wherein the engagement portions adhere the electrostatic device to the object when the attractive electrostatic force is applied by the electrostatic device to the engagement portion.

17. The apparatus according to claim 16, wherein device further has a chassis, and wherein each of the plurality of feet is movably connected to the chassis for locomotion of the device relative to the object.

18. The apparatus according to claim 15, wherein the ground element is a button-type structure that is substantially centrally located in the foot.

19. The apparatus according to claim 18, wherein the ground element extends through apertures in the insulation layer and the dielectric layer.

20. The apparatus according to claim 15, wherein each foot has a pair of engagement portions capable of maintaining static voltages, and wherein the attractive electrostatic forces generated by the robotic electrostatic device for each pair of engagement portions are generated from opposed positive and negative voltages.
